(19) United States
(12) Patent Application Publication
(10) Pub. No.: US 2020/0305292 A1
(43) Pub. Date: Sep. 24, 2020

(54) CONTROL DEVICE INSTALLATION APPARATUS AND CONTROL DEVICE UNIT

(71) Applicant: FANUC CORPORATION, Yamanashi (JP)

(72) Inventor: Taiki ENDOU, Yamanashi (JP)

(73) Assignee: FANUC CORPORATION, Yamanashi (JP)

(21) Appl. No.: 16/790,495

(22) Filed: Feb. 13, 2020

(30) Foreign Application Priority Data
Mar. 20, 2019 (JP) 2019-053008

(51) Int. Cl. H05K 5/00; H05K 7/20; H05K 5/02

(52) U.S. Cl. CPC H05K 5/0017; H05K 5/0247; H05K 5/0217; H05K 7/2039

(57) ABSTRACT

The control device installation apparatus enables a first control device or a second control device to be installed at a control panel in a selective manner, and includes: a housing configured to house the first control device or the second control device, and configured to be fastened to the control panel; a first control device fastener configured to fasten the first control device to the housing; a second control device fastener configured to fasten the second control device to the housing; a cable configured to electrically connect the first control device or the second control device to an outside of the housing; and a terminal block connectable to a terminal of the first control device or a terminal of the second control device, and connectable to a terminal of the cable.

This application is based on and claims the benefit of priority from Japanese Patent Application No. 2019-053008, filed. on 20 Mar. 2019, the content of which is incorporated herein by reference.

### BACKGROUND OF THE INVENTION

### Field of the Invention

The present disclosure relates to a control device installation apparatus and a control device unit including the control device installation apparatus.

### Related Art

For installation of a control device on a control panel, it has been common to develop a design based on the size of a selected control device and its interfaces (attachment and wiring). However, when replacement (substitution) of the control device is needed due to addition of a second source or in response to discontinuation of production, it may be required to change the wiring and the attachment parts. Such changes may result in an increase in the workload at a service site and an increase in the number of process steps required for the restoration/replacement. To address this problem involved in the replacement of control devices, it has been known to use an adaptor unit that makes the connection type of an existing control device and the connection type of a new control device conform to each other (see Patent Document 1).

Patent Document 1: Japanese Unexamined Patent Application, Publication No. 2011-181530

### SUMMARY OF THE INVENTION

The adaptor unit of this type is based on the assumption that the adapter is attached to a new control device in advance in a factory. Therefore, in the case where the adaptor needs to be attached to a new control device at a service site, it is not likely that a reduction is achieved in the workload at the service site and the number of process steps required for the restoration/replacement. Therefore, there has been a demand for a technique facilitating replacement of a control device installed at a control panel with another control device.

A first aspect of the present disclosure is directed to a control device installation apparatus for enabling a first control device or a second control device to be installed at a control panel in a selective manner. The control device installation apparatus includes: a housing configured to house the first control device or the second control device, and configured to be fastened to the control panel; a first control device fastener configured to fasten the first control device to the housing; a second control device fastener configured to fasten the second control device to the housing; a cable configured to electrically connect the first control device or the second control device to an outside of the housing; and a terminal block connectable to a terminal of the first control device or a terminal of the second control device, and connectable to a terminal of the cable.

A second aspect of the present disclosure is directed to a control device unit including: the control device installation apparatus of the first aspect; and the first control device or the second control device.

The present disclosure provides a control device installation apparatus that can facilitate replacement of a control device installed at a control panel. The present disclosure also provides a control device unit including the control device installation apparatus.

### BRIEF DESCRIPTION OF THE DRAWINGS

FIG. 1A is a schematic diagram of a control device installation apparatus according to a first embodiment of the present disclosure, and shows a state in which a control device unit having a first control device incorporated therein is provided.

FIG. 1B is a schematic diagram of the control device installation apparatus according to the first embodiment of the present disclosure, and shows a state in which the control device unit having a second control device incorporated therein is provided.

FIG. 2 is a schematic diagram of a control device installation apparatus according to a second embodiment of the present disclosure.

FIG. 3 is a schematic diagram of a control device installation apparatus according to a third embodiment of the present disclosure.

FIG. 4 is a schematic diagram of a control device installation apparatus according to a fourth embodiment of the present disclosure.

FIG. 5 is a schematic diagram of a control device installation apparatus according to a fifth embodiment of the present disclosure.

FIG. 6 is a schematic diagram of a control device installation apparatus according to a sixth embodiment of the present disclosure.

Embodiments of the present disclosure will be described in detail with reference to the drawings. In the description of each of second and subsequent embodiments, the same reference characters denote components and elements in common with the first embodiment or other embodiments, and the description of the components and elements in common will be omitted. Further, in the description of each of the second and subsequent embodiments, description of the same or similar effects to those achieved in the first embodiment or other embodiments will be omitted.

### First Embodiment

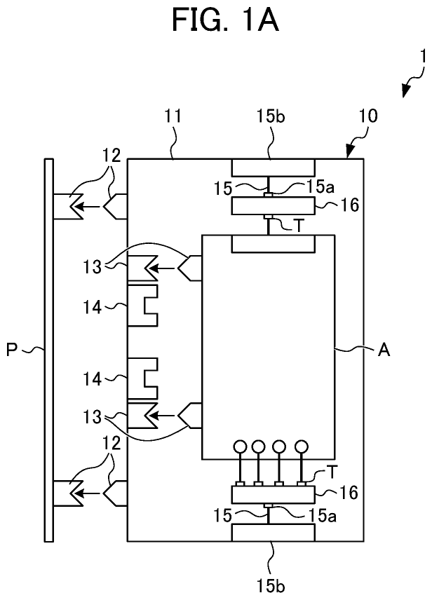

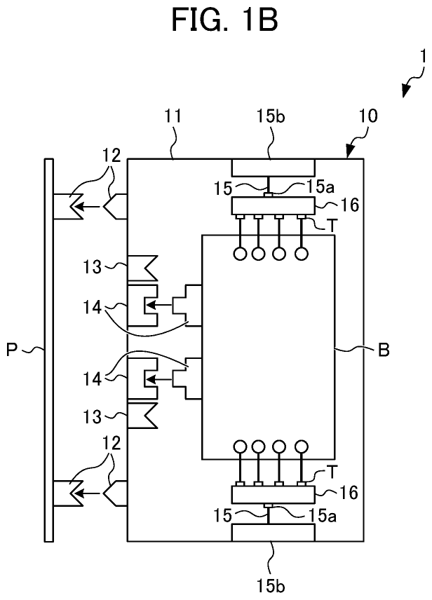

FIG. 1A is a schematic diagram of a control device installation apparatus according to a first embodiment of the present disclosure, and shows a state in which a control device unit having a first control device incorporated therein is provided. FIG. 1B is a schematic diagram of the control device installation apparatus according to the first embodiment of the present disclosure, and shows a state in which the control device unit having a second control device incorporated therein is provided.

As shown in FIGS. 1A and 1B, the control device installation apparatus 1 according to the present embodiment enables the first control device A or the second control device B to be installed at a control panel P in a selective manner. The control device unit 10 includes the control device installation apparatus 1 and the first control device A (see FIG. 1A) or a second control device B (see FIG. 1B), and is configured to be fastened to the control panel P. The control device unit 10 is provided with a housing 11, unit fasteners 12, first control device fasteners 13, second control device fasteners 14, cables 15, and terminal blocks 16, and has a selected one of the first control device A or the second control device B incorporated therein.

The housing 11 houses, for example, the first control device fasteners 13, the second control device fasteners 14, the cables 15, the terminal blocks 16, the selected one of the first control device A or the second control device B. The housing 11 is fastened to the control panel P via the unit fasteners 12. The unit fasteners 12 fasten the housing 11 to the control panel P. The unit fastener 12 includes, for example, a screw hole formed in the housing 11, and a screw, and functions in conjunction with a screw hole formed in the control panel P. The unit fasteners 12 fasten the housing 11 to the control panel P.

The first control device fasteners 13 fasten the first control device A to the housing 11. The first control device fastener 13 is composed of, for example, screw holes formed in the first control device A and the housing 11, and a screw. The second control device fasteners 14 fasten the second control device B to the housing 11. The second control device fastener 14 is composed of, for example, screw holes formed in the second control device B and the housing 11, and a screw. Selective use of the first control device fasteners 13 or the second control device fasteners 14 makes it possible to easily replace one control device with another in the housing 11.

The cables 15 electrically connect a selected one of the first control device A or the second control device B to the outside of the housing 11. Each cable 15 has a terminal 15a at one end, and a terminal 15b at the other end. The terminal 15a at the one end is connected to the terminal block 16. The other terminal 15b, which is provided at the end opposite to the terminal 15a connected to the terminal block 16, is fixed to the housing 11 such that the terminal 15b is exposed from the housing 11.

The terminal blocks 16 are disposed in the housing 11, and each relay between a selected one of the first control device A or the second control device B and the cable 15. Each terminal block 16 is connected to a terminal T of a selected one of the first control device A or the second control device B, and the terminal 15a provided at the one end of the cable 15. The control device unit 10 includes the plurality of cables 15 (e.g., two cables 15) and the plurality of terminal blocks 16 (e.g., two terminal blocks 16). The terminal block 16 is connectable to different numbers of terminals T of different types. Therefore, for example, as shown in FIGS. 1A and 1B, the terminal block 16 can absorb a difference in number and in type of the terminals T between the first control device A (having one terminal T disposed on an upper portion in FIG. 1A) and the second control device B (having four terminals T disposed in an upper portion in FIG. 1B).

According to the control device installation apparatus 1 of the present embodiment, the housing 11 absorbs a difference between the control devices. Therefore, when the first control device A or the second control device B needs to be replaced at a service site, due to addition of a second source or in response to discontinuation of production, the control device installation apparatus 1 can reduce the workload at the service site and the number of process steps required for the restoration/replacement. Thus, replacement of the control device installed at the control panel P can be facilitated. Further, since the relevant apparatus, devices and components are formed (unitized) into the control device unit 10, it is only necessary to replace the whole control device unit 10 incorporating the first control device A or the second control device B with another unit. As a result, an operator is less likely to contact with the first control device A or the second control device B, and protection against water and dust is enhanced, thereby making it easy to secure an IP protection class.

### Second Embodiment

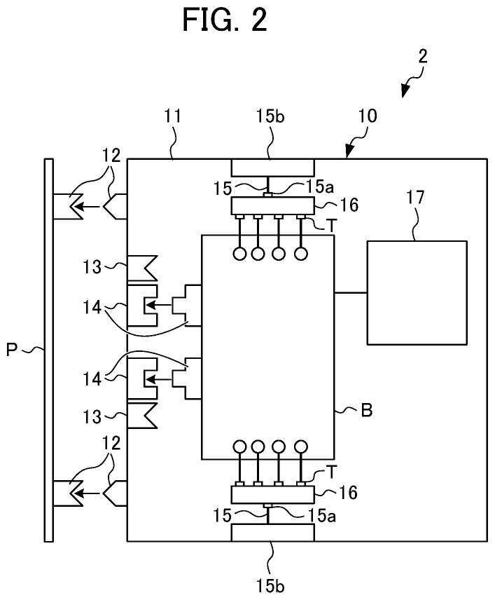

FIG. 2 is a schematic diagram of a control device installation apparatus according to a second embodiment of the present disclosure. The control device installation apparatus 2 according to the present embodiment differs from the control device installation apparatus of the first embodiment in that for example, the housing 11 of the second embodiment houses, in addition to the first control device A or the second control device B, another device 17 that is different from the first control device A and the second control device B.

As shown in FIG. 2, in the control device installation apparatus 2 according to the present embodiment, the control device unit 10 includes the device 17. For example, the device 17 is electrically connected to the second control device B, and functions in conjunction with the second control device B. Examples of the device 17 include a lamp, a relay, a fuse and a switch.

According to the control device installation apparatus 2 of the present embodiment, even if the first control device A alone is not functionally compatible with the second control device B alone, incorporating the device 17 that completes the function or adds a function in the control device unit 10 makes it possible to maintain the functional compatibility on the basis of each control device unit 10.

### Third Embodiment

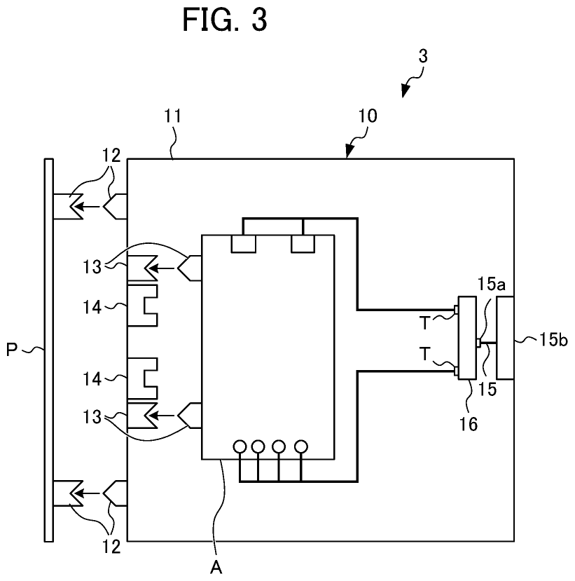

FIG. 3 is a schematic diagram of a control device installation apparatus according to a third embodiment of the present disclosure. As shown in FIG. 3, the control device installation apparatus 5 according to the present embodiment includes one terminal 15b at the other end of the cable 15 as a single integrated terminal. Therefore, the control device unit 10 includes one cable 15 and one terminal block 16.

Since the terminal 15b at the other end of the cable 15 is embodied as a single integrated terminal, the control device installation apparatus 3 according to the present embodiment can reduce the number of process steps required for the replacement and can reduce the amount of wiring in the control panel P.

### Fourth Embodiment

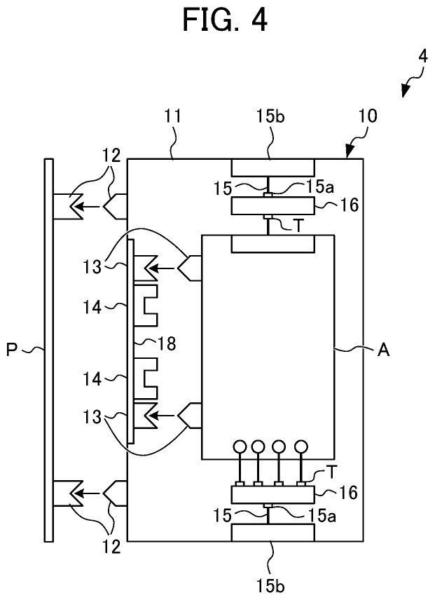

FIG. 4 is a schematic diagram of a control device installation apparatus according to a fourth embodiment of the present disclosure. The control device installation apparatus 4 of the present embodiment differs from the control device installation apparatus of the first embodiment in that, for example, the control device installation apparatus 4 includes a vibration suppressor 18 for suppressing vibration of the first control device A or the second control device B.

As shown in FIG. 4, in the control device installation apparatus 4 according to the present embodiment, the control device unit 10 includes the vibration suppressor 18. For example, the vibration suppressor 18 is constituted by an elastic member. The vibration suppressor 18 is disposed between the housing 11 and the first and second control device fasteners 13 and 14 as well as the first control device A or the second control device B. For example, the vibration suppressor 18 is fastened to the housing 11, together with the first control device A or the second control device B, by means of screws that are included in the first control device fasteners 13 or the second control device fasteners 14.

The control device installation apparatus 4 of the present embodiment, which includes the vibration suppressor 18, makes it possible to reduce vibration.

### Fifth Embodiment

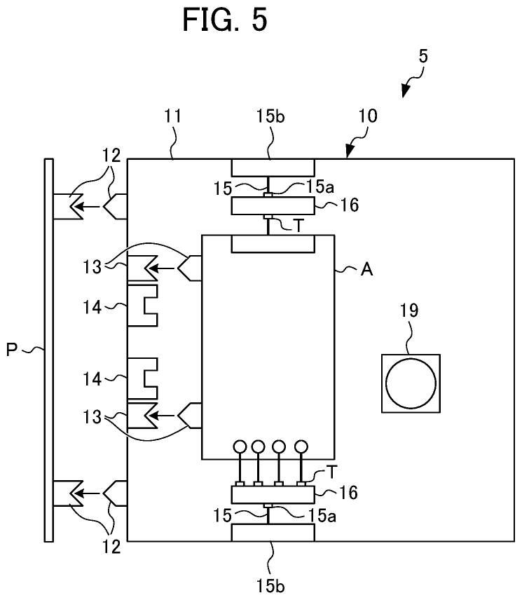

FIG. 5 is a schematic diagram of a control device installation apparatus according to a fifth embodiment of the present disclosure. The control device installation apparatus 5 of the present embodiment differs from the control device installation apparatus of the first embodiment in that, for example, the control device installation apparatus 5 includes a heat dissipator 19 for discharging heat in the housing 11 to the outside.

As shown in FIG. 5, in the control device installation apparatus 5 according to the present embodiment, the control device unit 10 includes the heat dissipator 19. For example, the heat dissipator 19 is disposed on the housing 11 so as to face both the inside and the outside of the housing 11, and is embodied as a fan that is driven by a motor.

The control device installation apparatus 5 according to the present embodiment, which includes the heat dissipator 19, can reduce heat generation.

### Sixth Embodiment

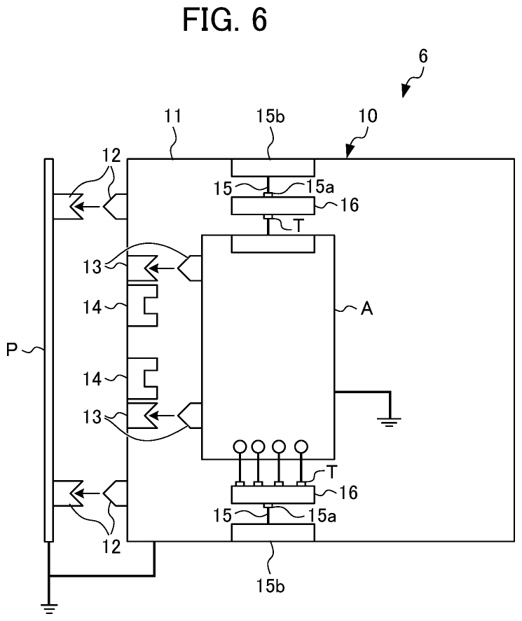

FIG. 6 is a schematic diagram of a control device installation apparatus according to a sixth embodiment of the present disclosure. The control device installation apparatus 6 of the present embodiment differs from the control device installation apparatus of the first embodiment in that, for example, the housing 11 of the control device installation apparatus 6 is made of metal.

As shown in FIG. 6, according to the control device installation apparatus 6 of the present embodiment, the housing 11 is made of metal. In the control device installation apparatus 6, a selected one of the first control device A or the second control device B is electrically connected to the housing 11. The control device installation apparatus 6 is grounded via the housing 11 and the control panel P that are electrically connected to the ground.

The control device installation apparatus 6 according to the present embodiment, of which the housing 11 is made of metal, can be grounded at a low impedance. As a result, improvement of noise resistance (electrical protection of the first control device A or the second control device B) can be achieved.

The embodiments of the present disclosure have been described in the foregoing. However, the present disclosure is not limited to the above-described embodiments. For example, the feature of each embodiment may be appropriately applied to a different embodiment. Further, in the embodiments, the most preferred effects resulting from the present disclosure are merely listed, and the effects of the present disclosure are not limited to those described in the embodiments.

Each of the above embodiments is configured such that one of two types of control devices (the first control device A or the second control device B) can be installed selectively. However, the present disclosure is not limited thereto. Each embodiment may be configured such that one of three or more types of control devices can be installed selectively. In that case, if focus is given to two types among the three types of control devices, each embodiment can be regarded to be configured such that one of the two types of control devices can be installed in a selective manner.

The control device according to the present disclosure is not limited to a device that controls the entire or part of a system, but generally refers to an electronic or electric device having an input portion or an output portion. Examples of the control device include signal input and output devices such as a computer and a programmable logic controller (PLC), displays such as a liquid crystal display (LCD), power supply devices such as a stabilized power supply and a transformer, protective devices such as an electromagnetic contactor and a fuse, electronic devices such as a relay and a switch, and measurement devices such as a sensor and a gauge.

### EXPLANATION OF REFERENCE NUMERALS

1, 2, 3, 4, 5, 6: Control Device Installation Apparatus
10: Control Device Unit
11: Housing
12: Unit Fastener
13: First Control Device Fastener
14: Second Control Device Fastener
15: Cable
15a, 15b: Terminal
16: Terminal Block
17: Device
18: Vibration Suppressor
19: Heat Dissipator
A: First Control Device
B: Second Control Device
P: Control Panel
T: Terminal

What is claimed is:

1. A control device installation apparatus for enabling a first control device or a second control device to be installed at a control panel in a selective manner, the control device installation apparatus comprising:
a housing configured to house the first control device or the second control device, and configured to be fastened to the control panel;
a first control device fastener configured to fasten the first control device to the housing;
a second control device fastener configured to fasten the second control device to the housing;
a cable configured to electrically connect the first control device or the second control device to an outside of the housing; and
a terminal block connectable to a terminal of the first control device or a terminal of the second control device, and connectable to a terminal of the cable.

2. The control device installation apparatus according to claim 1, wherein
the housing is capable of housing, in addition to the first control device or the second control device, another device that is different from the first control device and the second control device.

3. The control device installation apparatus according to claim 1, wherein
the cable 15 has a terminal at an end opposite to the terminal connectable to the terminal block, the terminal being embodied as a single integrated terminal.

4. The control device installation apparatus according to claim 1, further comprising:
a vibration suppressor that suppresses vibration of the first control device or vibration of the second control device.

5. The control device installation apparatus according to claim 1, further comprising:
a heat dissipator that dissipates heat in the housing to the outside.

6. The control device installation apparatus according to claim 1, wherein,
the housing is made of metal.

7. The control device installation apparatus according to claim 1, wherein
the housing, the first control device fastener, the second control device fastener, the cable, and the terminal block are unitized.

8. A control device unit comprising:
the control device installation apparatus according to claim 1; and
the first control device or the second control device.
